(19) United States
(12) Patent Application Publication
(10) Pub. No.: US 2015/0048839 A1
(43) Pub. Date: Feb. 19, 2015

(54) BATTERY FUEL GAUGE CALIBRATION

(71) Applicant: Broadcom Corporation, Irvine, CA (US)

(72) Inventor: Ryan Michael Desrosiers, Fort Collins, CO (US)

(73) Assignee: Broadcom Corporation, Irvine, CA (US)

(21) Appl. No.: 13/973,403

(22) Filed: Aug. 22, 2013

Related U.S. Application Data
(60) Provisional application No. 61/865,394, filed on Aug. 13, 2013.

(51) Int. Cl. G01R 31/36

(52) U.S. Cl. CPC G01R 31/3624
USPC 324/433

(57) ABSTRACT

Accurate charge measurement based on a calibration factor is described. According to certain aspects, the amount of charge stored in a battery is accumulated over time and adjusted using a calibration factor. In one embodiment, the calibration factor is determined by generating a replica current which comprises a scaled factor of a battery charging current. A calibration reference voltage is measured based on the replica current, and a charge reference voltage is measured based on the battery charging current. A calibration factor is determined based on the charge reference voltage and the calibration reference voltage. In turn, the amount of charge in a battery is accumulated over time using the calibration factor. In various embodiments, the calibration factor provides a factor by which a relatively-low tolerance reference circuit is adjusted, to achieve higher accuracy without substantially increased cost.

### CROSS-REFERENCE TO RELATED APPLICATIONS

This application claims the benefit of U.S. Provisional Application No. 61/865,394, filed Aug. 13, 2013, the entire contents of which is hereby incorporated herein by reference.

### BACKGROUND

Battery-powered computing systems and devices have been widely adopted for use in daily life. These systems and devices are designed to be more flexible and powerful, but are also more complex and consume more power. With advances in the design of battery-powered computing devices, the availability of sufficient power for the devices continues to be an ongoing concern. Because each new feature in a battery-powered computing device generally consumes charge from a battery, accurate measurement and/or estimation of the remaining amount of charge in the battery of the device is important.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 illustrates a system for battery fuel gauge calibration according to an example embodiment.

FIG. 2 illustrates further aspects of the battery charger in the system of FIG. 1 according to an example embodiment.

FIG. 3 illustrates further elements of a measurement circuit in the battery charger of FIG. 1 according to an example embodiment.

FIG. 4A illustrates representative charge reference voltages measured by the system of FIG. 1 according to an example embodiment.

FIG. 4B illustrates representative calibration reference and charge reference voltages measured by the system of FIG. 1 according to an example embodiment.

FIG. 5 illustrates a process flow diagram for a method of battery fuel gauge calibration performed by the system of FIG. 1 according to an example embodiment.

### DETAILED DESCRIPTION

Battery-powered computing systems are now designed to be more flexible and powerful, but are also more complex and consume more power. With advances in the design of battery-powered computing devices, the availability of sufficient power for the devices continues to be an ongoing concern. Because each new feature in a battery-powered computing device generally consumes charge from a battery, accurate measurement and estimation of the remaining amount of charge in the battery of the device is important.

Some battery-powered computing systems include power management processing circuitry that manages the supply of power in a system. This power management processing circuitry may be designed for certain needs, such as the need for accurate measurement and profiling of charge stored in a battery. Without accurate knowledge of the amount of charge stored in the battery, the battery-powered computing system may be susceptible to sporadic and unexpected shutdown, without warning, which may be frustrating to users. Further, such unexpected shutdown may result the critical data being lost, further tending to user frustration.

In this context, accurate charge measurement or integration over time based on a calibration factor is described herein. According to certain aspects, the amount of charge stored in a battery is accumulated over time and adjusted using a calibration factor. In one embodiment, the calibration factor is determined by generating a replica current which comprises a scaled factor of a battery charging current. A calibration reference voltage is measured based on the replica current, and a charge reference voltage is measured based on the battery charging current. A calibration factor is determined based on an evaluation of the charge reference voltage and the calibration reference voltage. In turn, the amount of charge in a battery is accumulated over time using the calibration factor. In various embodiments, the calibration factor provides a factor by which a relatively low-tolerance reference circuit is adjusted, to achieve higher accuracy without substantially increased cost.

Turning now to the drawings, an introduction and general description of exemplary embodiments of a system is provided, followed by a description of the operation of the same.

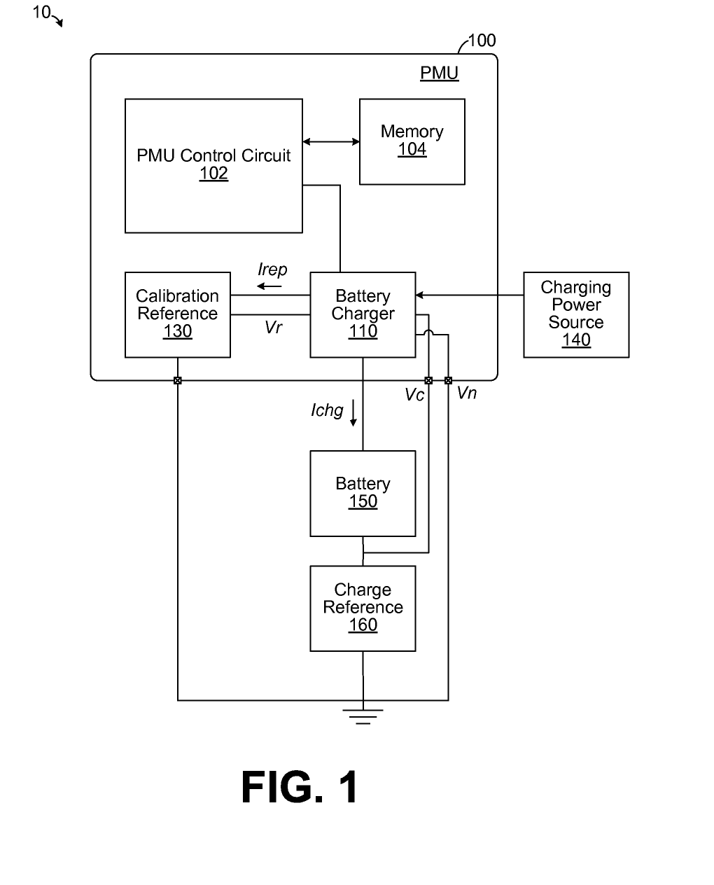

FIG. 1 illustrates a system 10 for battery fuel gauge calibration according to an example embodiment. The system 10 includes a Power Management Unit (PMU) 100, a charging power source 140, a battery 150, and a charge reference 160. In general, the PMU 100 controls the distribution of power from the battery 150 to elements of the system 10. In various embodiments, the system 10 may include several systems and subsystems, such as a host system on chip (SOC), a bluetooth/wireless local area network (WLAN) subsystem, a global positioning system (GPS) subsystem, a camera subsystem, a sensor subsystem, etc., for example, without limitation. Each of these system elements relies upon power from the battery 150. Generally, although not illustrated, the PMU 100 includes several power rails that condition and supply power from the battery 150 to the elements in the system 10.

The charging power source 140 may include any suitable power source for charging the battery 150. In various embodiments, the charging power source 140 may be capable of sourcing a suitable range of current (e.g., 100 ma-3 A) at a suitable voltage (e.g., 3.3-24 V) for charging the battery 150. The battery 150 may be embodied as any rechargeable battery suitable for the application, such as a lithium-ion, nickel-metal-hydride, or other battery variant, without limitation. The charge reference 160 includes a reference circuit element, such as a reference resistor, which is relied upon by the system 10 to determine an amount (e.g., magnitude) of the charging current Ichg that is supplied to charge the battery 150. As further described below, based on the amount of charging current Ichg, the system 10 may determine or estimate an amount of charge available in the battery 150. In connection with other variables, such as an output voltage of the battery 150, for example, the PMU 100 may maintain an estimated value of power or charge available in the battery 150 for use by the system 10.

The PMU 100 includes a PMU control circuit 102, a memory 104, a calibration reference 130, and a battery charger 110. Generally, the PMU control circuit 102 coordinates the operation of the PMU 100, as described herein. In this context, the PMU control circuit 102 may include one or more processing circuits, application specific circuitry, combinatorial logic, or any combination thereof, without limitation. As further described below, the PMU control circuit 102 may evaluate a charge reference voltage Vc (i.e., Vc−Vn) induced across the charge reference 160 based on the battery charging current Ichg, and evaluate a calibration reference voltage Vr (i.e., Vr−Vn) induced across the calibration reference 130 based on a replica current Irep. The PMU control circuit 102 may further determine a calibration factor based on an evaluation of one or more measurements of the charge reference voltage Vr and the calibration reference voltage Vc. As described herein, the calibration factor may be relied upon by the PMU 100 to more accurately estimate the amount of power or charge stored in the battery 150.

The memory 104 may be embodied as any suitable memory (e.g., volatile, non-volatile, etc.) for the application of storing information. The memory 104 may, in part, store computer-readable instructions thereon that, when executed by the PMU control circuit 102, for example, direct the PMU control circuit 102 to execute various aspects of the embodiments described herein.

The battery charger 110 includes circuitry for charging the battery 150 based on power supplied from the charging power source 140. In that context, the battery charger 110 includes a charging path circuit that couples the charging current Ichg to the battery 150, for charging the battery, and a replica current generator circuit that generates the replica current Irep, for evaluating the expected characteristics of the charge reference 160 and/or determining a calibration factor. In one embodiment, the replica current Irep includes a scaled magnitude or scaled factor of the battery charging current Ichg. The battery charger 110 further includes a measurement circuit that measures the charge reference voltage Vc across the charge reference 160 and measures the calibration reference voltage Vr across the calibration reference 130. In certain aspects of the embodiments, values of the charge and calibration reference voltages Vc and Vr are stored and evaluated by the PMU control circuit 102 for one or more values of the battery charging current Ichg and the replica current Irep. In other words, as further described below, the battery charger 110 varies the battery charging current Ichg and, proportionately, the replica current Irep. In turn, the measurement circuit of the battery charger 110 measures the charge and calibration reference voltages Vc and Vr for various values of the battery charging current Ichg and the replica current Irep.

The calibration reference 130 includes a reference circuit element, such as a known or determined impedance or reactance circuit element, which is relied upon by the system 10 to determine an amount (e.g., magnitude) of the replica current Irep. In various embodiments, the calibration reference 130 may be embodied as a circuit element of the PMU 100 itself, or it may be embodied as a circuit element external to the PMU 100. The calibration reference 130, in one embodiment, may include a high-tolerance reference resistance, such as a high-tolerance 1 or 10 Ω resistor, for example. In other embodiments, the calibration reference 130 may include a high-tolerance reference capacitance.

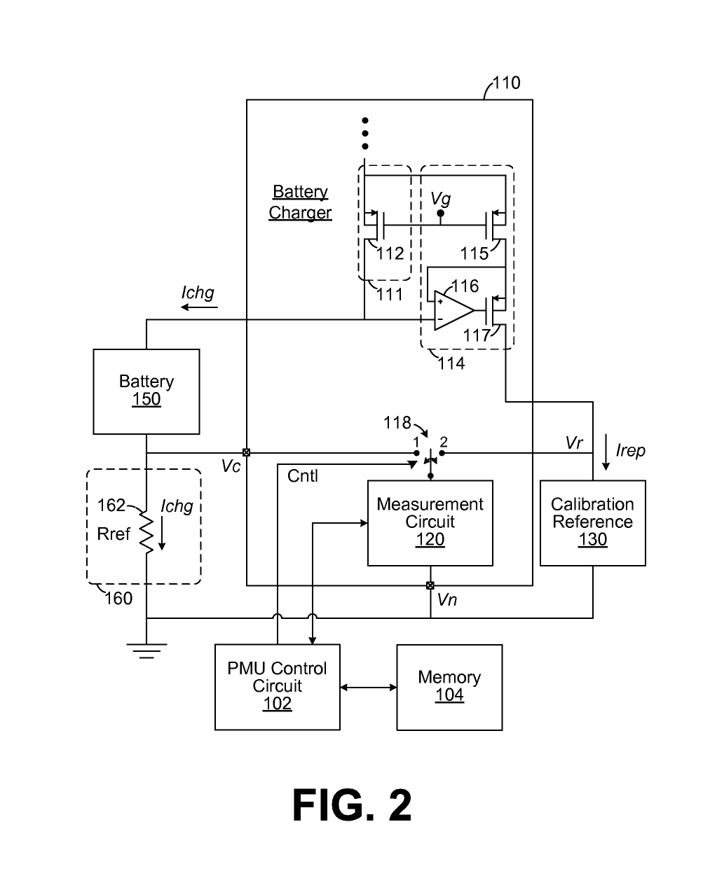

Before turning to FIG. 2, additional context for the battery evaluating circuitry in the system 10 is provided. Generally, the PMU 100 and/or the battery charger 110 should have an accurate means to determine or measure the state of charge stored in the battery 150. One manner to determine this state of charge includes integrating charge (i.e., current) that flows into and out of the battery 150. This charge may be estimated by measuring the voltage Vc across the charge reference 160, which is representative of the amount of current flowing into the battery 150. Measurements of the voltage Vc may be taken over time using an analog-to-digital (ADC) converter, for example, and accumulated. In one embodiment, the charge reference 160 may include a 0.01 Ω resistor, and the reference voltage Vc may be representative of the voltage differential across the 0.01 Ω resistor as the charging current Ichg charges the battery 150 and flows through the 0.01 Ω resistor.

In this context, it is noted that a significant source of error in the determination of the state of charge stored in the battery 150 may be attributable to the accuracy of the impedance of the charge reference 160 (e.g., the 0.01 Ω resistor), particularly due to its relatively small impedance value. Variations in the actual impedance of the charge reference 160 may be caused by resistor tolerance, printed circuit board layout variances, and manufacturing variability, for example, among other factors. Further, calibrating or evaluating the actual impedance value of the charge reference 160 in production is costly. It should be noted that the charge reference 160 cannot be increased to an arbitrarily large value to improve its accuracy and reduce manufacturing tolerance because, for example, increasing the impedance may result in an undesired increase in resistive power loss in the system 10.

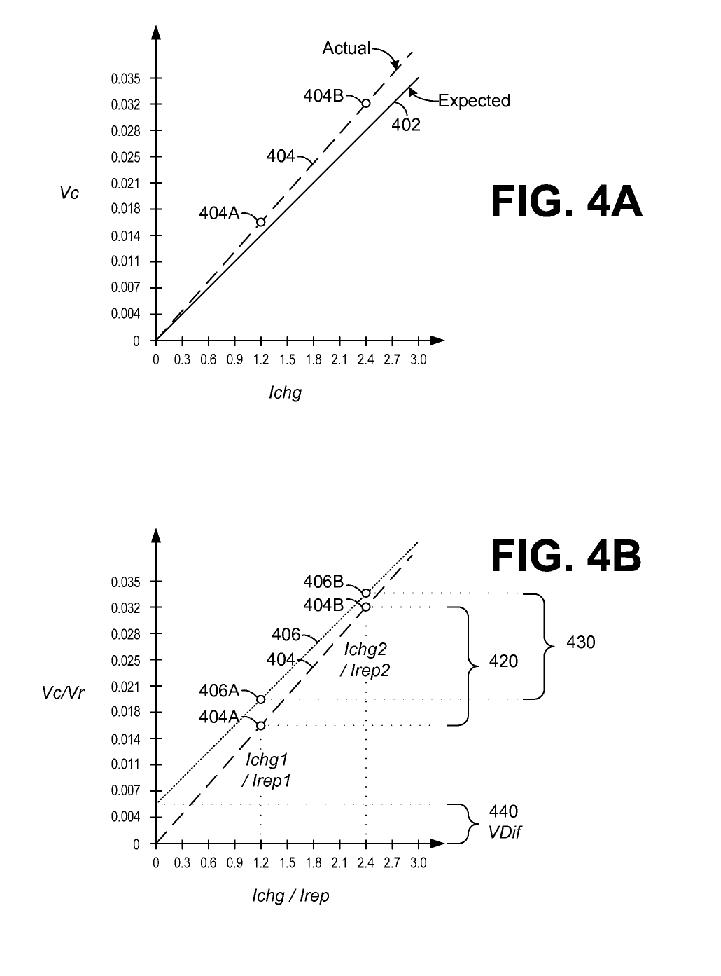

Turning briefly to FIG. 4A, representative charge reference voltages Vc measured by the system 10 of FIG. 1 are illustrated. In FIG. 4A, representative charge reference voltages Vc are plotted for various values of Ichg. An expected or ideal charge reference line 402 is illustrated. The expected charge reference line 402 is representative of expected values of Vc for various values of Ichg. For example, in an embodiment where the charge reference 160 is embodied as a reference resistor having a certain known resistance (e.g., 0.01 Ω), the expected charge reference line 402 is representative of expected voltage values measured across the known resistance for a range of values of Ichg.

Because the actual impedance value of the charge reference 160 is unlikely to be known with perfect precision, however, actual values (e.g., 404A and 404B) of Vc measured for various values of Ichg may deviate from the expected charge reference line 402, as illustrated in FIG. 4A. In this sense, the actual reference line 404 is representative of actual measured values of Vc for a range of values of Ichg. It is noted that, as the value of Ichg increases, so does the difference between actual and expected values of Vc. In this context, it should be appreciated that an inaccurate state of charge would be determined for a battery, if determined according to integrated Vc/Ichg values measured along the actual reference line 404. The inaccuracy is primarily due to the difference between the expected and actual values of Vc, stemming from imprecision or variability in the actual impedance value of the charge reference 160.

To ensure stable and expected system performance, some manufacturer's specifications specify that total error in a measured or estimated battery “state of charge” be no greater than 5%. This is attributed to the fact that, without accurate knowledge of battery state of charge, a system may be susceptible to sporadic and unexpected shutdown, without warning, which may be frustrating to users. Further, such unexpected shutdown may result the critical data being lost, further tending to user frustration.

In this context, the embodiments described herein provide a cost-effective and flexible means of more accurately evaluating and measuring the state of charge in the battery 150. As noted above and described in further detail below, the system 10 determines a calibration factor by which values of the reference voltage Vc and/or charge flowing into or out of the battery 150 may be adjusted to compensate for variability in the value of the charge reference 160. In this sense, the calibration factor may be relied upon to compensate for unknown resistor tolerances, printed circuit board layout variances, and manufacturing variabilities, for example, in the system 10.

FIG. 2 illustrates further elements and aspects of the battery charger 110 in the system 10 of FIG. 1 according to an example embodiment. As illustrated in FIG. 2, the battery charger 110 includes a charging path circuit 111, a replica current generation circuit 114, and a measurement circuit 120. The charge reference 160 is embodied as a reference resistor 162 in the embodiment of FIG. 2. The charging path circuit 111 includes a charging path transistor 112. The replica current generation circuit 114 includes a replica current transistor 115, a matching amplifier 116, and matching transistor 117. Generally, the matching amplifier 116 seeks to match the voltage at the drain of the replica current transistor 115 to that of the charging path transistor 112, via gate control of the matching transistor 117, to mirror the operating parameters (i.e., voltage biases) between the charging path transistor 112 and the replica current transistor 115.

To charge the battery 150, the charging path transistor 112 may couple and/or drive the charging current Ichg to the battery 150 and the reference resistor 162. Control of the charging current Ichg to the battery 150 may be actuated via control of the gate voltage Vg. The gate voltage Vg may be controlled by other circuit elements of the PMU 100, as needed, depending upon various factors including whether the power source 140 is coupled to the system 10 and whether the battery 150 is fully charged, for example.

The replica current Irep is generated by the replica current generation circuit 114 based on the gate voltage Vg. In one embodiment, the replica current transistor 115 is designed to provide a replica current Irep that comprises a scaled factor or amount of the current Ichg provided by the charging path transistor 112, for the same gate voltage Vg. In various embodiments, the scaled factor may be 10, 100, or 1000, for example, without limitation. To maintain symmetry in device characteristics, the charging path transistor 112 may be embodied as several (e.g., 10, 100, 1000, etc.) transistors of a certain gate width, for example, and the replica current transistor 115 may be embodied as a single transistor of the same gate width and formed in silicon together with (or proximate to) the transistors that form the charging path transistor 112. Thus, it should be appreciated that, as a matter of device characteristics, the replica current transistor 115 is likely to inherit operating characteristics that are substantially the same as or identical to the characteristics of the transistors which form the charging path transistor 112. As such, based on the scale factor, the replica current Irep is likely to be embodied as an accurate replica of 1/10^{th}, 1/100^{th}, 1/1000^{th}, etc. of the charging current Ichg.

In the example embodiment illustrated in FIG. 2, the measurement circuit 120 alternately measures the calibration reference voltage Vr, based on the replica current Irep, and measures the charge reference voltage Vc, based on the battery charging current Ichg. The switch 118, under control of the PMU control circuit 102, alternately couples the voltages Vc and Vr to the measurement circuit 120. In turn, the measurement circuit 120 converts the analog voltages Vc and Vr to digital values and, in connection with the PMU control circuit 102 and the memory 104, stores and evaluates the values as described in further detail below.

The charge reference voltage Vc and the calibration reference voltage Vr are alternately measured by the measurement circuit 120, depending upon the state of the switch 118. That is, for example, while a certain battery charging current Ichg is being supplied, the charge reference voltage Vc is measured with the switch 118 set to the position “1” according to the Cntl signal from the PMU control circuit 102. Before the battery charging current Ichg (and the replica current Irep) is changed in value (i.e., magnitude), the calibration reference voltage Vr is measured with the switch 118 set to the position “2” according to the Cntl signal from the PMU control circuit 102.

It is noted that, if the impedance of the calibration reference 130 is known to be, for example, 1000 times that of the reference resistor 162, and the value of the replica current is known to be, for example, substantially 1/1000^{th} that of the charging current Ichg, then the value of the calibration reference voltage Vr may be expected to be the same as the charge reference voltage Vc. More generally, if the calibration reference 130 is N times the reference resistance 162 and the replica current is scaled by a factor of 1/M, then the overall scale between the charge reference voltage Vc and the calibration reference voltage Vr can be set to N/M. Beyond this potential difference in scale, any difference between the values of the Vr and Vc voltages is attributed to deviations from expected impedance values of the reference resistor 162 and/or the calibration reference 130. If, however, the impedance of the calibration reference 130 can be selected, known, or characterized to certain a level of accuracy, any difference between the values of Vr and Vc may be attributed to a deviation from an expected impedance value of the reference resistor 162 alone.

In this context, the embodiments described herein evaluate the charge and calibration reference voltages Vc and Vr over different corresponding values of Ichg and Irep, to determine a calibration factor representative of a deviation between expected and actual values of the impedance of the reference resistor 162. For example, in one embodiment, the measurement circuit 120 samples first and second charge reference voltages Vc1 and Vc2, respectively, at first and second charge currents Ichg1 and Ichg2. The measurement circuit 120 also samples first and second calibration reference voltages Vr1 and Vr2, respectively, at first and second replica currents Irep1 and Irep2. In turn, the first and second charge reference voltages Vc1 and Vc2 and the first and second calibration reference voltages Vr1 and Vr2 are stored in the memory 104 and evaluated by the PMU control circuit 102. As further described below, the measurement circuit 120 may take additional sample measurements of Vc and Vr, depending upon factors such as accuracy, speed, available memory, etc.

When evaluating the charge and calibration reference voltages Vc1, Vc2, Vr1, and Vr2, the PMU control circuit 102 may determine a charge scale difference between the first charge reference voltage Vc1 and the second charge reference voltage Vc2 (e.g., Vc1−Vc2), and determine a calibration scale difference between the first calibration reference voltage Vr1 and the second calibration reference voltage Vr2 (e.g., Vr1−Vr2). The PMU control circuit 102 may further determine a calibration factor based on a ratio of the calibration scale difference and the charge scale difference. Additional discussion of the determination of the calibration factor is described below with reference to FIG. 4B.

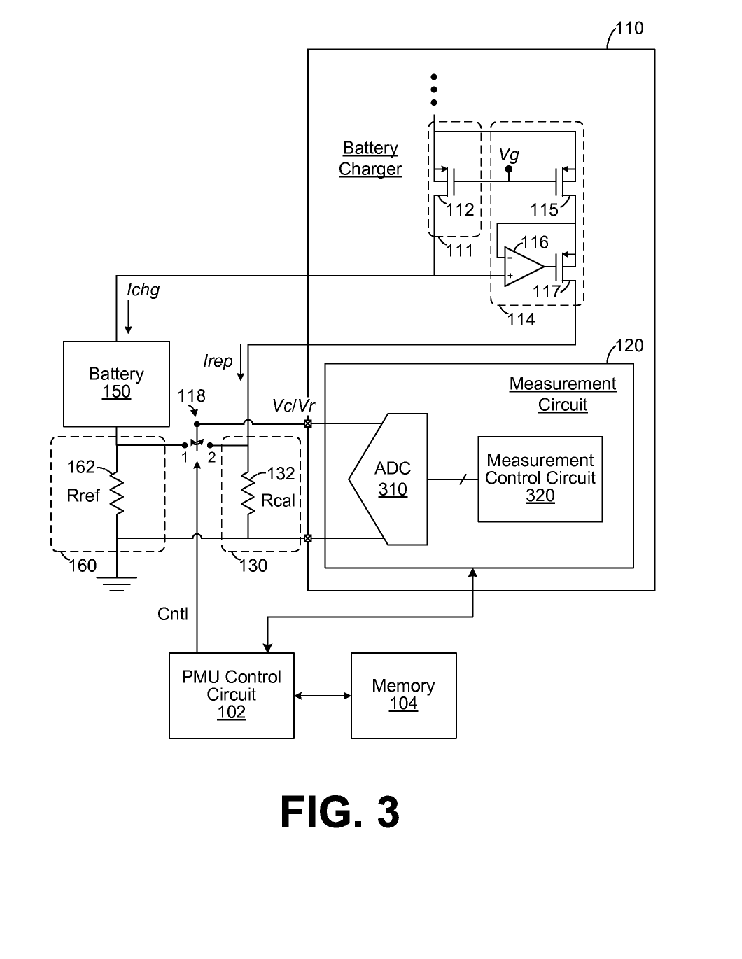

FIG. 3 illustrates further elements of the measurement circuit 120 in the battery charger 110 of FIG. 1 according to an example embodiment. In FIG. 3, the calibration reference 130 is embodied as a calibration resistor 132, and the measurement circuit 120 includes an ADC 310 and a measurement control circuit 320. The switch 118 couples the voltages Vc and Vr, alternatively over time, to the ADC 310 for measurement. The switch 118 may be controlled by the PMU control circuit 102 or, in other embodiments, by the measurement control circuit 320.

In various embodiments, the ADC 310 may convert an analog value into a digital n-bit representation of the analog value. The number of bits returned by the ADC 310 may vary among embodiments depending upon the number of bits needed for accurate measurements or other considerations. Under the supervision of the PMU control circuit 102, the measurement control circuit 320 controls the ADC 310 to sample the analog voltages Vc and Vr. The digital samples from the ADC 310 are returned to the PMU control circuit for storage and evaluation, as described herein.

It is noted that the calibration resistor 132 may be embodied as a circuit element external to the PMU 100. In one embodiment, the calibration resistor 132 may be embodied as relatively high-tolerance (i.e., high accuracy) 1, 10, or 100 Ω resistor, for example. It is further noted that a high-tolerance 10 or 100 Ω resistor is generally less costly than a high-tolerance 0.001 or 0.01 Ω resistor. Thus, according to aspects of the embodiments described herein, cost may be saved by selecting a low-tolerance reference resistor 162 and calibrating it against a relatively a high-tolerance calibration resistor 132.

In other embodiments, one or both of the charge reference 160 or the calibration reference 130 may be embodied as circuit elements other than resistors. For example, the calibration reference may be embodied as a high-tolerance capacitance, and the amount of charge stored in the capacitance over a certain period of time may be used to measure a voltage representative of the current Iref. This capacitance may be trimmed for accuracy after manufacturing, for example. In other variations, one or both of the charge reference 160 or the calibration reference 130 may be omitted. For example, the charge reference 160 may be omitted, and the amount of charge stored in the battery 150 may be determined only with reference to the current Iref and the calibration reference 130.

FIG. 4B illustrates representative calibration reference and charge reference voltages measured by the system 10 of FIG. 1 according to an example embodiment. As outlined above, the PMU control circuit 102 evaluates the charge and calibration reference voltages Vc and Vr measured at different corresponding values of Ichg and Irep to determine a calibration factor. The calibration factor may be representative of a deviation between expected and actual characteristics of the charge reference 160 (See e.g., FIGS. 1-3). As one example, the measurement circuit 120 (See e.g., FIGS. 2 and/or 3) samples first and second charge reference voltages Vc1 404A and Vc2 404B, respectively, at first and second charge currents Ichg1 and Ichg2. Further, the measurement circuit 120 samples first and second calibration reference voltages Vr1 406A and Vr2 406B, respectively, at first and second replica currents Irep1 and Irep2. It is noted that, in FIG. 4B, the scale of the x-axis values for Irep are scaled by a factor as compared to those for Ichg values, consistent with the embodiments described herein. In other words, for example, for a 1.2 A Ichg value and a 1/1000^{th} scale factor of Irep, the corresponding Irep value may comprise 1.2 mA. Similarly, the scale of the y-axis values for Vr are scaled by a factor as compared to those for the Vc values, consistent with the embodiments described herein.

After measurement, the first and second charge reference voltages Vc1 404A and Vc2 404B and the first and second calibration reference voltages Vr1 406A and Vr2 406B are stored in the memory 104 and evaluated by the PMU control circuit 102 (See e.g., FIGS. 2 and/or 3). It is noted that the number of different charge and calibration reference voltages Vc and Vr may vary, and the measurement of 2, 3, 4, or more references along the Vc charge line 404 and the Vr calibration line 406 is within the scope and spirit of the embodiments described herein. Generally, Vc and Vr values are measured for values of Ichg and Irep which cover a relatively wide operating range of the battery charger 110.

After storing the charge and calibration reference voltages Vc1 404A, Vc2 404B, Vr1 406A, and Vr2 4068, the PMU control circuit 102 determines a charge scale difference 420 between the first charge reference voltage Vc1 404A and the second charge reference voltage Vc2 404B, and determines a calibration scale difference 430 between the first calibration reference voltage Vr1 406A and the second calibration reference voltage Vr2 406B. The PMU control circuit 102 further determines a calibration factor based on a ratio, for example, of the calibration scale difference 430 and the charge scale difference 420.

In certain aspects, by working with the ratio of the calibration scale difference 430 and the charge scale difference 420, the PMU control circuit 102 normalizes, removes, or discounts the voltage differential 440, which may be generated as an inadvertent artifact of the replica current generation circuit 114 (See e.g., FIGS. 2 and/or 3). The ratio of the calibration scale difference 430 and the charge scale difference 420 may be used to adjust an accumulated value of charge into and out of the battery 150, over time. In other words, the PMU control circuit 102 may measure the calibration ratio from time to time, periodically, or at any suitable schedule for the system 10. Afterwards, the ongoing measurement of charge into and out of the battery 150, and the ongoing integration thereof, may be adjusted, in part, by the calibration ratio. For example, if the calibration factor indicates that the actual impedance value of the charge reference 160 is greater than the expected value, the estimated state or amount of charge stored in the battery 150 may be reduced. Similarly, if the calibration factor indicates that the actual impedance value of the charge reference 160 is less than the expected value, the estimated state or amount of charge stored in the battery 150 may be increased. The amount of the reduction or increase in the estimates state of charge may depend upon the value of the calibration ratio, consistent with the embodiments described herein.

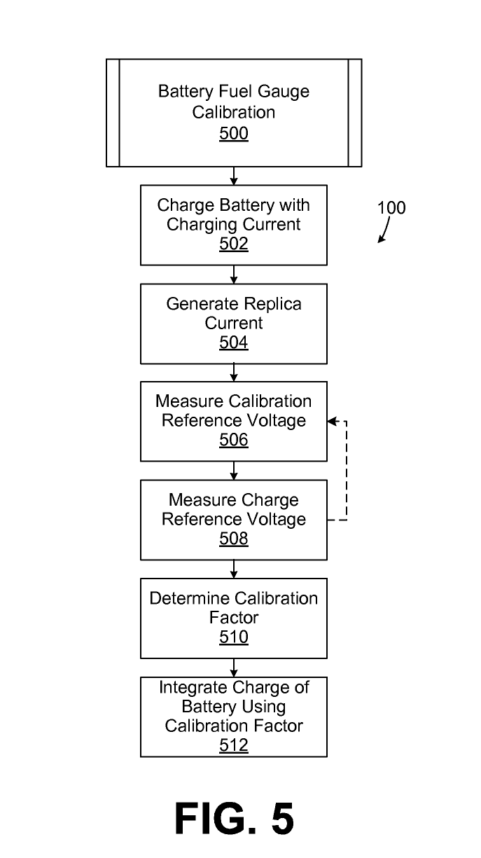

Turning to FIG. 5, a process flow diagram illustrating example processes performed by a system for battery fuel gauge calibration is illustrated. While the process flow diagram is described in connection with the system 10 of FIG. 1, it is noted that other systems may perform the illustrated processes. That is, in various embodiments, systems similar to the system 10 may perform the processes illustrated in FIG. 5.

In certain aspects, the flowcharts of FIG. 5 may be considered to depict example steps performed by the system 10 according to one or more embodiments. Although the process diagrams of FIG. 5 illustrate an order, it should be appreciated that the order may differ from that which is depicted. For example, an order of two or more elements in the process may be scrambled relative to that shown, performed concurrently, or performed with partial concurrence. Further, in some embodiments, one or more of the elements may be skipped or omitted within the scope and spirit of the embodiments described herein.

FIG. 5 illustrates a process flow diagram for a process 500 of battery fuel gauge calibration performed by the system of FIG. 1 according to an example embodiment. Starting at reference numeral 502, the process 500 generating a battery charging current and charging a battery with the battery charging current. With reference to FIGS. 2 and 3, for example, the battery charging current may be generated or supplied by the charging path transistor 112. Further, at reference numeral 504, the process 500 includes generating a replica current. In various embodiments, the replica current comprises a scaled factor of the battery charging current, such as 1/10^{th}, 1/100^{th}, or 1/1000^{th} of the charging current battery charging, as described herein.

At reference numeral 506, the process 500 includes measuring at least one calibration reference voltage based on the replica current. Measuring the calibration reference voltage may include measuring a voltage drop induced by the replica current across a calibration reference, as described herein. In one embodiment, at reference numeral 506, the process 500 includes sampling a first calibration reference voltage at a first replica current and sampling a second calibration reference voltage at a second replica current. The sampling and measurement of the first and second calibration reference voltages (e.g., Vr1 and Vr2) at reference numeral 506 may be preformed as described above with reference to FIGS. 2-4, for example. Once sampled and measured, the process 500 includes storing the first and second calibration reference voltages to a memory (e.g., the memory 104) at reference numeral 506.

At reference numeral 508, the process 500 includes measuring at least one charge reference voltage based on the battery charging current. Measuring the charge reference voltage may include measuring a voltage drop induced by the battery charging current across a charge reference. In one embodiment, at reference numeral 508, the process 500 includes sampling a first charge reference voltage at a first battery charging current and sampling a second charge reference voltage at a second battery charging current. The sampling and measurement of the first and second charge reference voltages (e.g., Vc1 and Vc2) at reference numeral 506 may be preformed as described above with reference to FIGS. 2-4, for example. Once sampled and measured, the process 500 includes storing the first and second charge reference voltages to a memory (e.g., the memory 104) at reference numeral 508.

The sampling and measuring at references 506 and 508 may be performed by the measurement circuit 120 as described herein. Between reference numerals 506 and 508, the measurement circuit 120 may switch between measuring voltages Vr across the calibration reference 130 and voltages Vc across the charge reference 160 (See FIGS. 2 and 3). Further, as illustrated by the dashed line in FIG. 5, it is noted that the processes at reference numerals 506 and 508 may be repeated, for example, for various values of battery charging and replica currents.

Continuing to reference numeral 510, the process 500 includes determining a calibration factor based on the measurements taken at reference numerals 506 and 508. In one embodiment, determining the calibration factor includes determining a calibration scale difference between the first calibration reference voltage and the second calibration reference voltage measured at reference numeral 506, and determining a charge scale difference between the first charge reference voltage and the second charge reference voltage measured at reference numeral 508. Further, at reference numeral 510, a ratio of the calibration scale difference and the charge scale difference may be calculated as the calibration factor. According to the example embodiments described above, the calibration factor may be determined or calculated by the PMU control circuit 102 based on the calibration and charge reference voltages stored in the memory 104.

At reference numeral 512, the process 500 includes integrating an amount of charge accumulated in the battery over time using the calibration factor. For example, according to the embodiments described above, the PMU control circuit 102 may measure the calibration ratio at reference numeral 510 from time to time, periodically, or at any suitable schedule. Afterwards, the ongoing measurement of charge into and out of the battery 150, and the ongoing integration thereof, may be adjusted, in part, by the calibration ratio. For example, if the calibration factor indicates that the actual impedance value of the charge reference 160 is greater than the expected value, the estimated state or amount of charge stored in the battery 150 may be reduced. Similarly, if the calibration factor indicates that the actual impedance value of the charge reference 160 is less than the expected value, the estimated state or amount of charge stored in the battery 150 may be increased. The amount of the reduction or increase in the estimates state of charge may depend upon the value of the calibration ratio, consistent with the embodiments described herein.

With regard to aspects of the structure or architecture of the system 10, in various embodiments, the PMU control circuit 102 or other processors or processing circuits of the system 10 may comprise general purpose arithmetic processors, state machines, or Application Specific Integrated Circuits (“ASICs”), for example. Each such processor or processing circuit may be configured to execute one or more computer-readable software instruction modules. In certain embodiments, each processor or processing circuit may comprise a state machine or ASIC, and the processes described in FIG. 5 may be implemented or executed by the state machine or ASIC according to the computer-readable instructions.

The memories and/or registers described herein may comprise any suitable memory devices that store computer-readable instructions to be executed by processors or processing circuits. These memories and/or registers store computer-readable instructions thereon that, when executed by the processors or processing circuits, direct the processors or processing circuits to execute various aspects of the embodiments described herein.

As a non-limiting example group, the memories and/or registers may include one or more of an optical disc, a magnetic disc, a semiconductor memory (i.e., a semiconductor, floating gate, or similar flash based memory), a magnetic tape memory, a removable memory, combinations thereof, or any other known memory means for storing computer-readable instructions.

In certain aspects, the processors or processing circuits are configured to retrieve computer-readable instructions and/or data stored on the memories and/or registers for execution. The processors or processing circuits are further configured to execute the computer-readable instructions to implement various aspects and features of the embodiments described herein.

Although embodiments have been described herein in detail, the descriptions are by way of example. The features of the embodiments described herein are representative and, in alternative embodiments, certain features and elements may be added or omitted. Additionally, modifications to aspects of the embodiments described herein may be made by those skilled in the art without departing from the spirit and scope of the present invention defined in the following claims, the scope of which are to be accorded the broadest interpretation so as to encompass modifications and equivalent structures.

1. A method, comprising:
generating a replica current which comprises a scaled factor of a battery charging current;
measuring, with a measurement circuit, a calibration reference voltage based on the replica current;
measuring, with the measurement circuit, a charge reference voltage based on the battery charging current; and
determining a calibration factor based on the charge reference voltage and the calibration reference voltage.

2. The method of claim 1, further comprising integrating an amount of charge accumulated in a battery over time using the calibration factor.

3. The method of claim 1, wherein measuring the calibration reference voltage comprises measuring a voltage drop induced by the replica current across a calibration reference.

4. The method of claim 1, further comprising switching, with the measurement circuit, between measuring the calibration reference voltage and the charge reference voltage.

5. The method of claim 1, wherein measuring the calibration reference voltage comprises:
sampling a first calibration reference voltage at a first replica current;
sampling a second calibration reference voltage at a second replica current; and
storing the first calibration reference voltage and the second calibration reference voltage to a memory.

6. The method of claim 5, wherein measuring the charge reference voltage comprises:
sampling a first charge reference voltage at a first battery charging current;
sampling a second charge reference voltage at a second battery charging current; and
storing the first charge reference voltage and the second charge reference voltage to a memory.

7. The method of claim 6, wherein determining the calibration factor comprises:
determining a calibration scale difference between the first calibration reference voltage and the second calibration reference voltage; and
determining a charge scale difference between the first charge reference voltage and the second charge reference voltage.

8. The method of claim 7, further comprising determining the calibration factor based on a ratio of the calibration scale difference and the charge scale difference.

9. A system, comprising:
a battery; and
a power management unit comprising:
a charging path circuit that couples a battery charging current to the battery;
a replica current circuit that generates a replica current of the battery charging current;
a measurement circuit that measures a calibration reference voltage based on the replica current and measures a charge reference voltage based on the battery charging current; and
a control circuit that determines a calibration factor based on the charge reference voltage and the calibration reference voltage.

10. The system of claim 9, wherein the control circuit integrates an amount of charge accumulated in the battery over time using the calibration factor.

11. The system of claim 9, wherein the measurement circuit measures the calibration reference voltage based on a voltage drop induced by the replica current across a calibration reference.

12. The system of claim 9, further comprising a switch that couples at least one of the calibration reference voltage and the charge reference voltage to the measurement circuit.

13. The system of claim 9, wherein the measurement circuit:
samples a first calibration reference voltage at a first replica current;
samples a second calibration reference voltage at a second replica current; and
stores the first calibration reference voltage and the second calibration reference voltage to a memory.

14. The system of claim 13, wherein the measurement circuit:
samples a first charge reference voltage at a first battery charging current;
samples a second charge reference voltage at a second battery charging current; and
stores the first charge reference voltage and the second charge reference voltage to a memory.

15. The system of claim 14, wherein the control circuit:
determines a calibration scale difference between the first calibration reference voltage and the second calibration reference voltage; and
determines a charge scale difference between the first charge reference voltage and the second charge reference voltage.

16. The system of claim 15, wherein the control circuit further determines the calibration factor based on a ratio of the calibration scale difference and the charge scale difference.

17. A method, comprising:
measuring, with a measurement circuit, a charge reference voltage based on a battery charging current;
measuring, with the measurement circuit, a calibration reference voltage based on a replica current of the battery charging current;
determining a calibration factor based on the charge reference voltage and the calibration reference voltage; and
integrating an amount of charge accumulated in a battery over time using the calibration factor.

18. The method of claim 17, wherein measuring the calibration reference voltage comprises:
sampling a first calibration reference voltage at a first replica current; and
sampling a second calibration reference voltage at a second replica current.

19. The method of claim 18, wherein measuring the charge reference voltage comprises:
sampling a first charge reference voltage at a first battery charging current; and
sampling a second charge reference voltage at a second battery charging current.

20. The method of claim 19, further comprising determining the calibration factor based on a ratio of a difference between the first calibration reference voltage and the second calibration reference voltage and a difference between the first charge reference voltage and the second charge reference voltage.
